(19) United States
(12) Patent Application Publication
(10) Pub. No.: US 2025/0208034 A1
(43) Pub. Date: Jun. 26, 2025

(54) APPARATUS AND METHOD FOR MEASURING ELECTRON DENSITY OF PLASMA

(71) Applicant: Research & Business Foundation Sungkyunkwan University, Suwon-si (KR)

(72) Inventors: Moon Soo BAK, Suwon-si (KR); Cheol Woo BONG, Suwon-si (KR); Kyun Ho KIM, Suwon-si (KR)

(73) Assignee: Research & Business Foundation Sungkyunkwan University, Suwon-si (KR)

(21) Appl. No.: 19/001,711

(22) Filed: Dec. 26, 2024

(30) Foreign Application Priority Data
Dec. 26, 2023 (KR) 10-2023-0191834

(51) Int. Cl. G01N 21/31

(52) U.S. Cl. CPC G01N 21/31; G01N 2201/06113

(57) ABSTRACT

Disclosed herein are an apparatus and a method for measuring an electron density of plasma. The method of measuring an electron density of plasma includes emitting multiple laser beams into plasma through different paths through a laser diode, detecting an intensity of each of the multiple laser beams passing through the plasma through a photodiode and generating absorption data indicating an extent to which energy of each laser beam is reduced by an inverse bremsstrahlung process occurring in the plasma, and calculating an electron density of the plasma for each concentric zone on the basis of the absorption data.

### CROSS-REFERENCE TO RELATED APPLICATION

This application claims priority to and the benefit of Korean Patent Application No. 10-2023-0191834, filed on Dec. 26, 2023, the disclosure of which is incorporated herein by reference in its entirety.

### BACKGROUND

### 1. Field of the Invention

The present invention relates to an apparatus and method for measuring an electron density of plasma, and more specifically, to an apparatus and method for measuring an electron density of plasma, which can measure an electron density of high-density plasma.

### 2. Discussion of Related Art

There is no diagnostic tool that directly measures a state of high-density plasma used in semiconductor device manufacturing processes such as extreme ultraviolet (EUV) lithography and pulsed laser deposition (PLD) processes. Conventionally, a state of plasma is measured using a contact sensor (such as a Langmuir probe) for targeting plasma downstream. However, the plasma state measurement method using the contact sensor is an invasive measurement method, and since the sensor is damaged during a diagnosis process and a sensor surface is coated with a metal material, it is unsuitable as a continuous condition monitoring tool.

Meanwhile, optical emission spectroscopy (OES) is mainly used as a non-invasive plasma state diagnosis tool, and the OES infers an electron density, which is a major plasma state quantity, from an emission line ratio or emission line width of plasma after quenching for a certain period of time. The conventional OES method, which utilizes emission lines to measure electron density through broadening of the spectral linewidth, provides valid measurements for relatively low electron densities (as low as 10¹⁸ cm⁻³) after the plasma begins to emit light. However, in cases such as high-density laser-induced plasma, where the initial electron density exceeds 10¹⁹ cm⁻³ at the early stages of plasma generation, the OES method is limited by overlapping emission lines in the spectrum, making it difficult to clearly identify peaks, and self-absorption, which distorts the collected spectrum. Therefore, the conventional OES method utilizing emission lines is unsuitable for measuring the electron density of high-density EUV sources (over 10¹⁹ cm⁻³) or laser-induced plasma in PLD processes.

Another non-invasive method of plasma diagnostics involves Thomson scattering, which is widely recognized as an accurate way to measure the electron density and temperature of the plasma. However, this method requires highly sophisticated equipment and a high level of expertise in plasma physics to implement. For this reason, Thomson scattering is difficult to apply experimentally, and quantifying the signal can be tricky, especially in complex conditions such as dense laser-induced plasmas.

Therefore, there is a need for a technology that can non-invasively, economically, and continuously measure a state of high-density plasma used in semiconductor processes such as EUV lithography and a PLD process.

The related art of the present invention is disclosed in Korean Registered Patent No. 10-2053720 (Dec. 3, 2019).

### SUMMARY OF THE INVENTION

The present invention is directed to providing an apparatus and method for measuring an electron density of plasma, which can measure an electron density of high-density plasma in real time.

According to an aspect of the present invention, there is provided a method of measuring an electron density of plasma, which includes emitting multiple laser beams into plasma through different paths through a laser diode, detecting an intensity of each of the multiple laser beams passing through the plasma through a photodiode and generating absorption data indicating an extent to which energy of each laser beam is reduced by an inverse bremsstrahlung process occurring in the plasma, and calculating an electron density of the plasma for each concentric zone on the basis of the absorption data.

The calculating of the electron density may include calculating absorbance of the plasma for each path from the absorption data, calculating an absorption coefficient of the plasma for each concentric zone from the absorbance data, and calculating an electron density of the plasma for each concentric zone from the absorption coefficient for each concentric zone.

The calculating of the absorbance of the plasma for each path may include calculating the absorbance of the plasma for each path from the absorption data using the Beer-Lambert law.

The calculating of the absorption coefficient for each concentric zone may include performing a tomographic reconstruction based on absorption data measured for each path to calculate the absorption coefficient corresponding to each concentric zone in the plasma.

The calculating of the electron density for each concentric zone may include calculating the electron density of the plasma for each concentric zone from the absorption coefficient for each concentric zone using the following equation 1:

$$κ ( λ ) = \frac{{C}_{1} {n}_{e}^{2} {λ}^{3}}{2 {hc}^{2} {T}_{e}^{1 / 2}} [ 1 - exp ( - \frac{hc}{λ {kT}_{e}} ) + 2 {ξ}_{{N}^{+}} \frac{{g}_{{N}^{+} , 1}}{{U}_{{N}^{+}}} ( cosh ( - \frac{hc}{λ {kT}_{e}} ) - 1 ) ] \qquad [ Equation 1 ]$$

(Here, κ denotes an absorption coefficient, λ denotes a wavelength, C₁ denotes

$$1.63 \times {10}^{- 43} W {m}^{4} {K}^{\frac{1}{2}} s {r}^{- 1} ,$$

nₑ denotes an electron density (cm⁻³), h denotes Planck constant, C denotes a speed of light in a vacuum, Tₑ denotes an electron temperature, k denotes a Boltzmann constant, ξ denotes a Biberman factor, g denotes ground-state degeneracy, and U denotes a partition function.)

The method may further include, before the calculating of the electron density for each concentric zone, detecting a spontaneous emission intensity of the plasma for each path and generating spontaneous emission data representing the spontaneous emission intensity of the plasma for each path, and correcting the absorption data for each path according to the spontaneous emission data.

According to another aspect of the present invention, there is provided an apparatus for measuring an electron density of plasma, which includes a laser diode configured to emit a laser beam, a photodiode configured to detect an intensity of the laser beam, and a processor connected to the laser diode and the photodiode, wherein the processor emits multiple laser beams into the plasma through different paths through the laser diode, detects an intensity of each of the multiple laser beams passing through the plasma through the photodiode, generates absorption data for each path representing an extent to which energy of each laser beam is reduced by an inverse bremsstrahlung process occurring in the plasma, and calculates an electron density of the plasma for each concentric zone on the basis of the absorption data.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram illustrating an apparatus for measuring an electron density of plasma according to an embodiment of the present invention;

FIG. 2 is a flowchart illustrating a method of measuring an electron density of plasma according to an embodiment of the present invention;

FIG. 3 is an exemplary diagram illustrating a verification device for verifying the method of measuring an electron density of plasma according to an embodiment of the present invention; and

FIGS. 4A to 4C are exemplary diagrams illustrating results of measuring the electron density of plasma using the method of measuring an electron density of plasma according to an embodiment of the present invention.

### DETAILED DESCRIPTION OF EXEMPLARY EMBODIMENTS

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) on the “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to each other.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

Hereinafter, an apparatus and method for measuring an electron density of plasma according to an embodiment of the present invention will be described in detail with reference to the accompanying drawings.

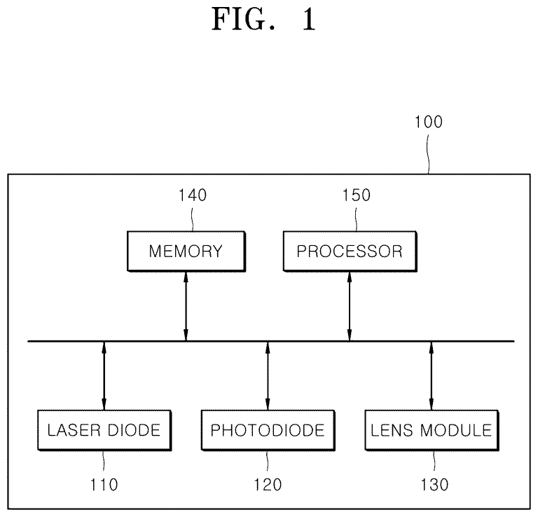

FIG. 1 is a block diagram illustrating an apparatus for measuring an electron density of plasma according to an embodiment of the present invention.

Referring to FIG. 1, an apparatus 100 for measuring an electron density of plasma according to the embodiment of the present invention may include a laser diode 110, a photodiode 120, a lens module 130, a memory 140, and a processor 150. Each component included in the apparatus 100 for measuring an electron density of plasma according to the embodiment of the present invention may be connected through a common bus or may be connected through an individual interface or an individual bus based on the processor 150. The apparatus 100 for measuring an electron density of plasma according to the embodiment of the present invention may further include various components in addition to the components shown in FIG. 1, or some of the components may be omitted.

The laser diode 110 may emit a laser beam into plasma under the control of the processor 150. A user may determine the laser diode 110 used to measure an electron density of plasma by considering an electron density level of the plasma that is a measurement target. For example, when an electron density with a level of 10¹⁸ to 10²⁰ cm⁻³, a laser diode 110 for emitting a laser beam with a wavelength of about 1 micrometer (μm) may be used to measure the electron density of the plasma.

The photodiode 120 may detect an intensity of the laser beam passing through the plasma and output the detected intensity to the processor 150. The user may determine the photodiode 120 used to measure the electron density of the plasma by considering a time resolution level of the electron density of the plasma that is a measurement target. For example, since a lifetime of high-density plasma is very short, from hundreds of nanoseconds (ns) to several microseconds (μs), a photodiode 120 with a short response time of several nanoseconds may be used to measure the electron density of the plasma.

The lens module 130 may adjust a beam diameter of the laser beam emitted from the laser diode 110. The user may determine the lens module 130 by considering a spatial resolution level of the electron density of the plasma that is a measurement target. For example, the lens module 130 may change the beam diameter of the laser beam emitted from the laser diode 110 to a level of tens of micrometers. In addition, the lens module 130 may branch the laser beam emitted from the laser diode 110 into multiple laser beams. Multiple laser beams may be branched off from the laser beam, which is emitted from the laser diode 110, by the lens module 130 and pass through the plasma through different paths.

The apparatus 100 for measuring an electron density of plasma according to the embodiment of the present invention may include a plurality of photodiodes 120. In the apparatus 100 for measuring an electron density of plasma, as many photodiodes 120 as the number of laser beams branched by the lens module 130 may be provided. Each photodiode 120 may be used to detect an intensity of a branch of a laser beam branched by the lens module 130.

At least one command executed by the processor 150 may be stored in the memory 140. The memory 140 may be implemented as a volatile storage medium and/or a non-volatile storage medium, for example, as a read only memory (ROM) and/or a random access memory (RAM).

The memory 140 may store a variety of information required in the operation of the processor 150 operates. In addition, the memory 140 may store various types of information calculated while the processor 150 operates.

The processor 150 may be operatively connected to the laser diode 110, the photodiode 120, the lens module 130, and the memory 140. The processor 150 may be implemented as a central processing unit (CPU) or a system on chip (SoC), may run an operating system or an application to control a plurality of hardware or software components connected to the processor 150, and may perform various data processing and arithmetic operations. The processor 150 may execute at least one command stored in the memory 140 and store the execution result data in the memory 140.

The processor 150 may emit the multiple laser beams into the plasma through different paths through the laser diode 110 and the lens module 130. The processor 150 may emit the laser beam through the laser diode 110, and the laser beam may be branched into the multiple laser beams by the lens module 130 to be emitted to the plasma.

The processor 150 may detect the intensity of each of the multiple laser beams passing through the plasma through the photodiode 120 and generate absorption data indicating the extent to which energy of each laser beam is reduced by an inverse bremsstrahlung process occurring in the plasma. The absorption data may include path-specific information about the extent to which the energy of the laser beam is reduced (the extent to which the energy is absorbed by the plasma).

When the laser beam is emitted to the plasma, an inverse bremsstrahlung process may occur, and thus the energy of the laser beam may be absorbed into the plasma. As the inverse bremsstrahlung process progresses, the energy (intensity) of the laser beam may decrease, and thus the energy of the laser beam after passing through the plasma may decrease compared to the energy of the laser beam before passing through the plasma. Since the extent to which the energy of the laser beam is reduced by the inverse bremsstrahlung process, or in other words, the extent to which the energy is absorbed by the plasma (the intensity of the inverse bremsstrahlung process), is a function of an electron density, the electron density of the plasma may be derived from information on the extent to which the energy of the laser beam is reduced by the inverse bremsstrahlung process.

The processor 150 may detect a spontaneous emission intensity for each path in the plasma, generate spontaneous emission data representing the spontaneous emission intensity for each path in the plasma, and correct absorption data according to the generated spontaneous emission data. Since a plasma spontaneous emission phenomenon may affect the process of detecting the intensity of the laser beam through the photodiode 120, it is necessary to correct an influence of the plasma spontaneous emission phenomenon. Therefore, according to the present embodiment, the influence of the plasma spontaneous emission phenomenon may be corrected by correcting the absorption data according to the spontaneous emission data. The spontaneous emission data may include information on an intensity of the spontaneous emission of the plasma for each path. The spontaneous emission data may be generated by detecting the intensity of the beam through the photodiode 120 without emitting the laser beam through the laser diode 110.

The processor 150 may calculate an electron density of the plasma for each concentric zone on the basis of the absorption data. The processor 150 may calculate absorbance of the plasma for each path from the absorption data, calculate an absorption coefficient (extinction coefficient) of the plasma for each concentric zone from the absorbance data, and calculate an electron density of the plasma for each concentric zone from the absorption coefficient for each concentric zone.

The processor 150 may calculate the absorbance of the plasma for each path from the absorption data using the Beer-Lambert law. The Beer-Lambert law is known to those skilled in the art to which the present invention pertains, and thus a detailed description thereof will be omitted.

The processor 150 may calculate the absorption coefficient of the plasma for each concentric zone from the absorbance data using tomographic reconstruction. Since a waist size of the laser beam is not very small compared to a size of the plasma, it is important to consider a shape of the laser beam in order to accurately interpret the electron density of the plasma. The processor 150 may use the Abel transform as a tomography reconstruction method for one-dimensional spatial distribution and the Radon transform as the tomography reconstruction method for two-dimensional spatial distribution. The tomography reconstruction is known to those skilled in the art to which the present invention pertains, and thus a detailed description thereof will be omitted.

The processor 150 may calculate the electron density of the plasma for each concentric zone from the absorption coefficient of the plasma for each concentric zone using the following equation 1. The absorption coefficient of the laser beam with an arbitrary wavelength may be defined by the following equation 1. The processor 150 may calculate the electron density of the plasma for each concentric zone by performing a process of substituting the acquired absorption coefficient, the expected electron temperature of the plasma, and the wavelength of the laser beam into the following equation 1, thereby calculating the electron density of the plasma.

$$κ ( λ ) = \frac{{C}_{1} {n}_{e}^{2} {λ}^{3}}{2 {hc}^{2} {T}_{e}^{1 / 2}} [ 1 - exp ( - \frac{hc}{λ {kT}_{e}} ) + 2 {ξ}_{{N}^{+}} \frac{{g}_{{N}^{+} , 1}}{{U}_{{N}^{+}}} ( cosh ( - \frac{hc}{λ {kT}_{e}} ) - 1 ) ] \qquad [ Equation 1 ]$$

Here, κ may denote an absorption coefficient, λ may denote a wavelength, C₁ may denote

$$1.63 \times {10}^{- 43} W {m}^{4} {K}^{\frac{1}{2}} s {r}^{- 1} ,$$

nₑ may denote an electron density (cm⁻³), h may denote Planck constant, c may denote a speed of light in a vacuum, Tₑ may denote an electron temperature, k may denote a Boltzmann constant, ξ may denote a Biberman factor, g may denote ground-state degeneracy, and U may denote a partition function.

Information on the electron density of the plasma may be used to optimize a process using plasma. Semiconductor device manufacturing is carried out in different chambers, and chamber matching as well as process optimization for each chamber is very important for securing a semiconductor yield. For optimization of plasma processes and the chamber matching between the plasma processes, plasma state diagnosis and feedback control of process parameters through the plasma state diagnosis are very important. According to the present invention, a state change of high-density plasma in real time can be measured to be provided to a device for controlling semiconductor processes (EUV lithography and a PLD process), and the device can achieve chamber matching by performing feedback control to perform optimization on the basis of the received information on the state change of the high-density plasma.

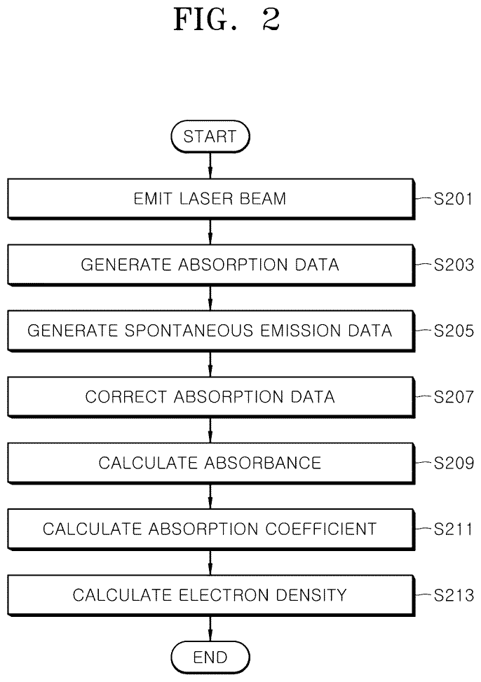

FIG. 2 is a flowchart illustrating a method of measuring an electron density of plasma according to an embodiment of the present invention.

Hereinafter, with reference to FIG. 2, the method of measuring an electron density of plasma will be described focusing on the operation of the processor 150. Some of the processes, which will be described below, may be performed in an order different from the order described below, or may be omitted. Meanwhile, detailed description of the overlapping configuration with the above-described content will be omitted below and the description will focus on a time-series configuration.

First, the processor 150 may emit the multiple laser beams into the plasma through different paths through the laser diode 110 and the lens module 130 (S201).

Subsequently, the processor 150 may detect an intensity of each of the multiple laser beams passing through the plasma through the photodiode 120 and generate absorption data indicating the extent to which energy of each laser beam is reduced by an inverse bremsstrahlung process occurring in the plasma (S203).

Then, the processor 150 may detect a spontaneous emission intensity for each path in the plasma (S205), generate spontaneous emission data representing the spontaneous emission intensity for each path in the plasma, and correct absorption data according to the generated spontaneous emission data (S207).

Next, the processor 150 may calculate absorbance of the plasma for each path from the absorption data (S209). The processor 150 may calculate the absorbance of the plasma for each path from the absorption data using the Beer-Lambert law.

Subsequently, the processor 150 may calculate an absorption coefficient of the plasma for each concentric zone from the absorbance data (S211). The processor 150 may calculate the absorption coefficient of the plasma for each concentric zone from the absorbance data using tomographic reconstruction.

Next, the processor 150 may calculate the electron density of the plasma for each concentric zone from the absorption coefficient of the plasma for each concentric zone (S213). The processor 150 may calculate the electron density of the plasma for each concentric zone from the absorption coefficient of the plasma for each concentric zone using the above equation 1.

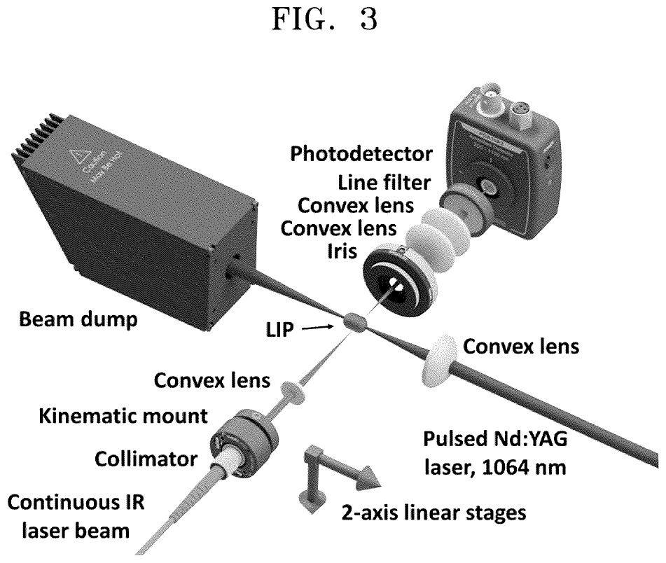

FIG. 3 is an exemplary diagram illustrating a verification device for verifying the method of measuring an electron density of plasma according to an embodiment of the present invention.

The verification device shown in FIG. 3 may include some components of the apparatus 100 for measuring an electron density of plasma according to the embodiment of the present invention. The verification device may generate high-density plasma in the air by focusing a pulsed laser with a lens. The verification device may include a laser diode and a photodiode, emit a laser beam to the high-density plasma through the laser diode, and detect an intensity of the laser beam passing through the high-density plasma through the photodiode.

The verification device may measure absorbance data for multiple laser paths and determine the spatiotemporal distribution of the plasma's electron density by moving the laser diode and photodiode through a linear stage and repeatedly performing operations of emitting the laser beam and detecting the intensity of the laser beam. For example, the verification device may measure the absorbance data by moving the laser diode and the photodiode by 50 μm outward from the center of the plasma. The verification device may adjust a diameter of the laser beam emitted from the laser diode through a separate lens.

Meanwhile, although the laser diode and the photodiode are moved through the linear stage to measure the absorbance data for the multiple paths in the above-described embodiment, when a fiber coupler or a fan beam is used, the absorbance data for the multiple paths may be measured simultaneously, and in this case, a spatiotemporal distribution of the electron density of the plasma may be confirmed in real time.

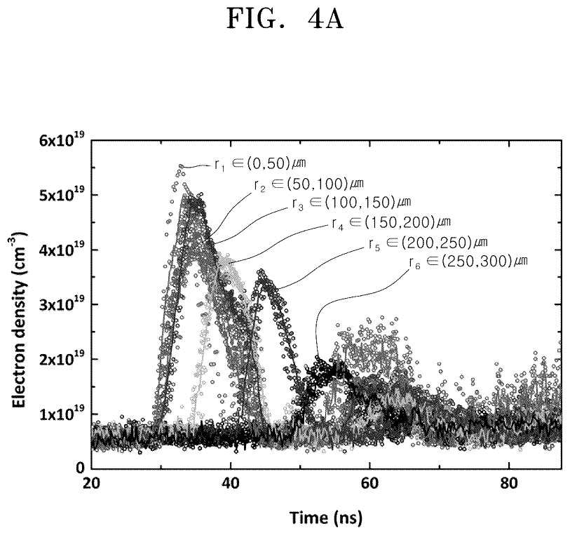

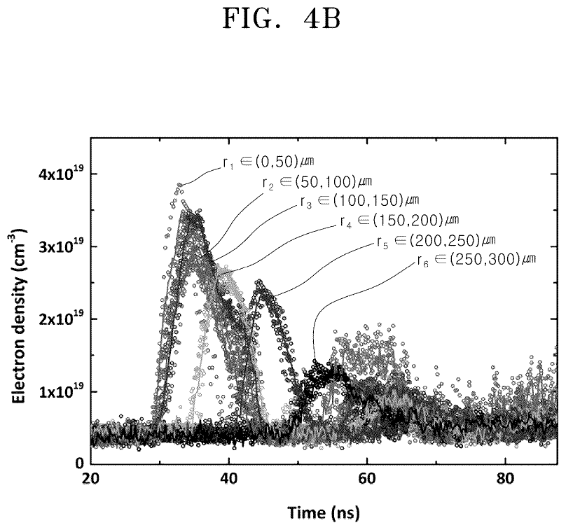

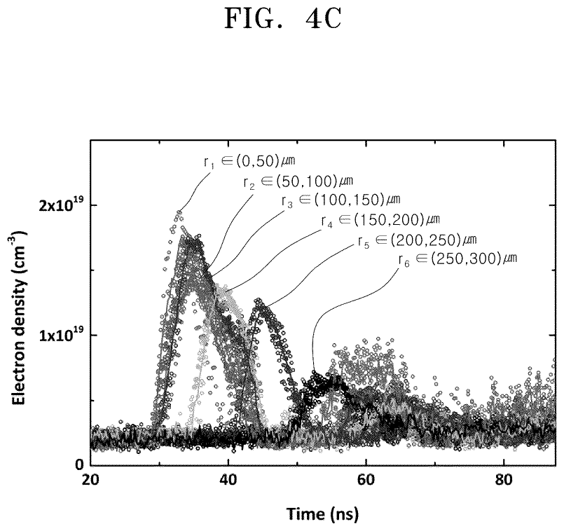

FIGS. 4A to 4C are exemplary diagrams illustrating results of measuring the electron density of plasma using the method of measuring an electron density of plasma according to an embodiment of the present invention.

FIG. 4A shows measurement results of the electron densities of plasma when the electron temperature is 6 eV, FIG. 4B shows measurement results of the electron densities of the plasma when the electron temperature is 4 eV, and FIG. 4C shows measurement results of the electron densities of the plasma when the electron temperature is 2 eV. As shown in FIGS. 4A to 4C, according to the present embodiment, the spatiotemporal distribution of the electron density of the plasma may be confirmed with high accuracy.

The electron density distribution shown in FIGS. 4A to 4C are based on an analysis of a plasma region divided into concentric zones according to an embodiment of the present invention. Each of the concentric zones defined at 50 micrometer (μm) intervals outwardly from the center of the plasma has a unique absorption coefficient value, and the electron density was calculated based on this. The electron density in each zone is based on the absorption coefficient of each concentric zone calculated by tomographic reconstruction of the absorbance data measured for each path, which accurately reflects the spatiotemporal evolution of the plasma. Thus, the electron density distribution shown in FIGS. 4A to 4C represent the diffusion and density evolution with time from the initial development of the plasma to a high degree of accuracy.

As described above, according to one aspect of the present invention, the apparatus and method for measuring an electron density of plasma according to the embodiment of the present invention can monitor the spatiotemporal distribution of the electron density of the high-density plasma in real time.

In addition, the apparatus and method for measuring an electron density of plasma according to the embodiment of the present invention can measure the electron density of that high-density plasma using a low-cost laser diode and a low-cost photodiode at a lower cost than the existing equipment.

Implementations described herein may also be implemented by, for example, a method or process, an apparatus, a software program, a data stream, or a signal. Even when only discussed in the context in a single form of implementation (e.g., discussed only as a method), the implementation of features discussed may also be implemented in other forms (e.g., an apparatus or program). The apparatus may be implemented in suitable hardware, software, and firmware. The method may be implemented in an apparatus such as a processor, which is generally referred to as a processing device including, for example, a computer, a microprocessor, an integrated circuit, or a programmable logic device. The processor also includes communication devices such as computers, cellular phones, portable/personal digital assistants (PDAs), and other devices that facilitate information communication of between end-users.

According to one aspect of the present invention, a spatiotemporal distribution of an electron density of a high-density plasma can be monitored in real time.

According to one aspect of the present invention, the electron density of the high-density plasma can be measured using a low-cost laser diode and a low-cost photodiode at a lower cost than the existing equipment.

Meanwhile, it should be noted that effects of the present invention are not limited to the above-described effects, and other effects that are not described above can be clearly understood by those skilled in the art from the above description.

While the present invention has been described with reference to embodiments shown in the drawings, these embodiments are merely illustrative and it should be understood that various modifications and other equivalent embodiments can be derived by those skilled in the art on the basis of the embodiments. Therefore, the true technical scope of the present invention should be defined by the appended claims.

What is claimed is:

1. A method of measuring an electron density of plasma, which is performed by a computing device including a processor, the method comprising:
emitting multiple laser beams into plasma through different paths through a laser diode;
detecting an intensity of each of the multiple laser beams passing through the plasma through a photodiode and generating absorption data indicating an extent to which energy of each laser beam is reduced by an inverse bremsstrahlung process occurring in the plasma; and
calculating an electron density of the plasma for each concentric zone on the basis of the absorption data.

2. The method of claim 1, wherein the calculating of the electron density includes:
calculating absorbance of the plasma for each path from the absorption data;
calculating an absorption coefficient of the plasma for each concentric zone from the absorbance data; and
calculating an electron density of the plasma for each concentric zone from the absorption coefficient for each concentric zone.

3. The method of claim 2, wherein the calculating of the absorbance of the plasma for each path includes calculating the absorbance of the plasma for each path from the absorption data using the Beer-Lambert law.

4. The method of claim 2, wherein the calculating of the absorption coefficient for each concentric zone includes calculating the absorption coefficient for each concentric zone from the absorbance data using tomographic reconstruction.

5. The method of claim 2, wherein the calculating of the electron density for each concentric zone includes calculating the electron density of the plasma for each concentric zone from the absorption coefficient for each concentric zone using the following equation 1:
$$κ ( λ ) = \frac{{C}_{1} {n}_{e}^{2} {λ}^{3}}{2 {hc}^{2} {T}_{e}^{1 / 2}} [ 1 - exp ( - \frac{hc}{λ {kT}_{e}} ) + 2 {ξ}_{{N}^{+}} \frac{{g}_{{N}^{+} , 1}}{{U}_{{N}^{+}}} ( cosh ( \frac{hc}{λ {kT}_{e}} ) - 1 ) ] \qquad [ Equation 1 ]$$
(here, κ denotes an absorption coefficient, λ denotes a wavelength, C₁ denotes
$$1.63 \times {10}^{- 43} W {m}^{4} {K}^{\frac{1}{2}} s {r}^{- 1} ,$$
nₑ denotes an electron density (cm⁻³), h denotes Planck constant, c denotes a speed of light in a vacuum, Tₑ denotes an electron temperature, k denotes a Boltzmann constant, ξ denotes a Biberman factor, g denotes ground-state degeneracy, and U denotes a partition function.)

6. The method of claim 1, further comprising,
before the calculating of the electron density for each concentric zone, detecting a spontaneous emission intensity of the plasma for each path and generating spontaneous emission data representing the spontaneous emission intensity of the plasma for each path; and
correcting the absorption data according to the spontaneous emission data.

7. An apparatus for measuring an electron density of plasma, the apparatus comprising:
a laser diode configured to emit a laser beam;
a photodiode configured to detect an intensity of the laser beam; and
a processor connected to the laser diode and the photodiode,
wherein the processor emits multiple laser beams into the plasma through different paths through the laser diode, detects an intensity of each of the multiple laser beams passing through the plasma through the photodiode, generates absorption data representing an extent to which energy of each laser beam is reduced by an inverse bremsstrahlung process occurring in the plasma, and calculates an electron density of the plasma for each concentric zone on the basis of the absorption data.

8. The apparatus of claim 7, wherein the processor calculates absorbance of the plasma for each path from the absorption data, calculates an absorption coefficient of the plasma for each concentric zone from the absorbance data, and calculates an electron density of the plasma for each concentric zone from the absorption coefficient for each concentric zone.

9. The apparatus of claim 8, wherein the processor calculates the absorbance of the plasma for each path from the absorption data using the Beer-Lambert law.

10. The apparatus of claim 8, wherein the processor calculates the absorption coefficient for each concentric zone from the absorbance data using tomographic reconstruction.

11. The apparatus of claim 8, wherein the processor calculates the electron density of the plasma for each concentric zone from the absorption coefficient for each concentric zone using the following equation 1:
$$κ ( λ ) = \frac{{C}_{1} {n}_{e}^{2} {λ}^{3}}{2 {hc}^{2} {T}_{e}^{1 / 2}} [ 1 - exp ( - \frac{hc}{λ {kT}_{e}} ) + 2 {ξ}_{{N}^{+}} \frac{{g}_{{N}^{+} , 1}}{{U}_{{N}^{+}}} ( cosh ( \frac{hc}{λ {kT}_{e}} ) - 1 ) ] \qquad [ Equation 1 ]$$
(here, κ denotes an absorption coefficient, λ denotes a wavelength, C₁ denotes
$$1.63 \times {10}^{- 43} W {m}^{4} {K}^{\frac{1}{2}} s {r}^{- 1} ,$$
nₑ denotes an electron density (cm⁻³), h denotes Planck constant, c denotes a speed of light in a vacuum, Tₑ denotes an electron temperature, k denotes a Boltzmann constant, ξ denotes a Biberman factor, g denotes ground-state degeneracy, and U denotes a partition function.)

12. The apparatus of claim 7, wherein the processor detects a spontaneous emission intensity for each path in the plasma, generates spontaneous emission data representing the spontaneous emission intensity for each path in the plasma, and corrects absorption data according to the generated spontaneous emission data.
